(19) United States
(12) Patent Application Publication
(10) Pub. No.: US 2026/0344340 A1
(43) Pub. Date: Oct. 29, 2026

(54) INFORMATION PROCESSING METHOD, COMPUTER PROGRAM, INFORMATION PROCESSING APPARATUS, AND SUBSTRATE PROCESSING SYSTEM

(71) Applicant: Tokyo Electron Limited, Tokyo (JP)

(72) Inventor: Wataru SUWA, Miyagi (JP)

(73) Assignee: Tokyo Electron Limited, Tokyo (JP)

(21) Appl. No.: 19/701,846

(22) Filed: Jun. 9, 2026

Related U.S. Application Data
(63) Continuation of application No. PCT/JP2024/043978, filed on Dec. 12, 2024.

(30) Foreign Application Priority Data
Dec. 15, 2023 (JP) 2023-212459

(51) Int. Cl. H10P 72/00; H01J 37/32

(52) U.S. Cl. CPC H10P 72/0604; H01J 37/32926; H01J 37/32935; H01J 2237/3343

(57) ABSTRACT

An information processing method including: acquiring distribution information of irregularities on a surface of a chamber internal component of a substrate processing apparatus at a first time point; acquiring distribution information of irregularities of the chamber internal component at a second time point after substrate processing is performed from the first time point; and predicting distribution information of irregularities of the chamber internal component at a time point after the substrate processing is performed from the second time point, based on the acquired distribution information at the first time point and distribution information at the second time point.

### CROSS-REFERENCE TO RELATED APPLICATIONS

This application is a bypass continuation application of International Application No. PCT/JP2024/043978 having an international filing date of Dec. 12, 2024 and designating the United States, the International Application being based upon and claiming the benefit of priority from Japanese Patent Application No. 2023-212459, filed on Dec. 15, 2023, the entire contents of each of which are incorporated herein by reference.

### BACKGROUND

### Field

The present disclosure relates to an information processing method, a computer program, an information processing apparatus, and a substrate processing system.

### Description of Related Art

JP2021-61442A proposes a system in which an annular main body of an edge ring used inside a chamber for processing a semiconductor substrate is provided with a trigger feature that includes a micro chamber disposed below a surface of the main body and a cap element covering the micro chamber, and a wear level and a remaining lifetime of the edge ring are determined based on the micro chamber seen when the surface is eroded by exposure to a plasma. In this system, the wear level and remaining lifetime of the edge ring are determined based on an image obtained by imaging the trigger feature with an inspection scope inside the chamber.

### SUMMARY

The present disclosure provides an information processing method including: acquiring distribution information of irregularities on a surface of a chamber internal component of a substrate processing apparatus at a first time point; acquiring distribution information of irregularities of the chamber internal component at a second time point after substrate processing is performed from the first time point; and predicting distribution information of irregularities of the chamber internal component at a time point after the substrate processing is performed from the second time point, based on the acquired distribution information at the first time point and distribution information at the second time point.

### BRIEF DESCRIPTION OF DRAWINGS

The scope of the present disclosure is best understood from the following detailed description of exemplary embodiments when read in conjunction with the accompanying drawings.

FIG. 1 is a schematic diagram illustrating an overview of an information processing system according to the present embodiment.

FIG. 2 is a block diagram illustrating a configuration example of an information processing apparatus according to the present embodiment.

FIG. 3 is a schematic plan view illustrating a configuration example of a focus ring disposed in a substrate processing apparatus in the information processing system according to the present embodiment.

FIG. 4 is a schematic cross-sectional view taken along a line A-A in FIG. 3.

FIG. 5 is a flowchart illustrating an example of a procedure of lifetime prediction processing performed by the information processing apparatus according to the present embodiment.

FIG. 6 is a schematic diagram illustrating a display example of a first measurement result.

FIG. 7 is a schematic diagram illustrating a display example of a second measurement result.

FIG. 8 is a schematic diagram illustrating calculation of a change amount by the information processing apparatus.

FIG. 9 is a schematic diagram illustrating an example of prediction of a frequency distribution by the information processing apparatus.

FIG. 10 is a schematic diagram illustrating examples of a predicted value and a measured value of a frequency distribution.

FIG. 11 is a schematic diagram illustrating an example of lifetime prediction by the information processing apparatus.

FIG. 12 is a schematic diagram illustrating a configuration example of a substrate processing system 100 according to a second embodiment.

FIG. 13 is a schematic diagram illustrating a configuration example of a pick 192A of a transfer arm 190 of the substrate processing system 100 according to the second embodiment.

FIG. 14 is a block diagram illustrating a configuration example of the substrate processing system 100 according to the second embodiment.

FIG. 15 is a flowchart illustrating an example of a procedure of lifetime prediction processing performed by the substrate processing system 100 according to the second embodiment.

FIG. 16 is a flowchart illustrating an example of a procedure of lifetime prediction processing performed by the substrate processing system 100 according to a third embodiment.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### System Overview

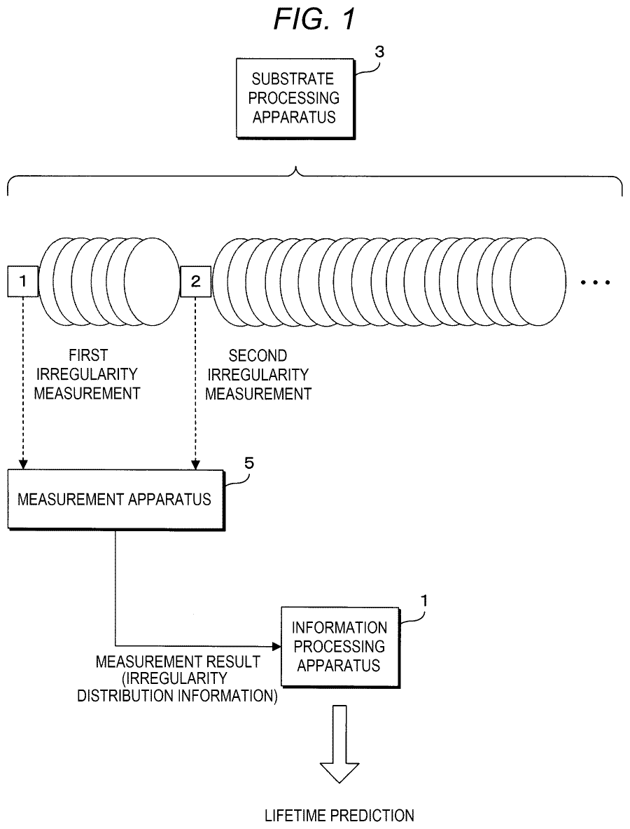

FIG. 1 is a schematic diagram illustrating an overview of an information processing system according to the present embodiment. The information processing system according to the present embodiment includes an information processing apparatus 1, a substrate processing apparatus 3, a measurement apparatus 5, and the like. The substrate processing apparatus 3 includes a process chamber for performing etching processing on a substrate such as a semiconductor wafer. In order to process a surface of the substrate into a desired shape, for example, the etching processing is processing in which the surface of the substrate is scraped by forming a gas into a plasma to cause ions to collide with the substrate in a chamber as a vacuum environment.

In the present embodiment, the substrate processing apparatus 3 is an apparatus that performs the etching processing on the semiconductor wafer. However, the present disclosure is not limited thereto, and the substrate processing apparatus may be, for example, an apparatus that performs the etching processing on metal, glass, and the like. In the present embodiment, the substrate processing apparatus 3 is an apparatus that performs so-called dry etching as the etching processing. However, the present disclosure is not limited thereto, and may be an apparatus that performs so-called wet etching.

The etching processing is performed in a sealed chamber. However, in addition to the substrate to be processed, various components constituting the chamber are present in the chamber. These components present in the process chamber are exposed to chemicals and the like during the etching processing to scrape the surface, and thus the components deteriorate as the etching processing is repeatedly performed. For example, when the deterioration of the components in the chamber exceeds a predetermined reference, a user such as an administrator or an operator of the substrate processing apparatus 3 needs to replace the deteriorated components. In the present embodiment, a focus ring (edge ring) will be described by way of example as a chamber internal component. However, the chamber internal component is not limited to the focus ring, and may be any component disposed in the chamber. The information processing system according to the present embodiment is a system that predicts a timing when it becomes necessary to replace the chamber internal component of the substrate processing apparatus 3, that is, a lifetime of the component.

The information processing apparatus 1 is, for example, an apparatus that monitors and controls an operation of the substrate processing apparatus 3, and may be implemented by using a general-purpose personal computer or a server computer, or a dedicated controller. In the present embodiment, the information processing apparatus 1 is connected to the measurement apparatus 5 via a signal line, a network, and the like, and performs processing of acquiring irregularity distribution information of the chamber internal component of the substrate processing apparatus 3, which is measured by the measurement apparatus 5, and predicting the lifetime of the chamber internal component based on the acquired information.

The measurement apparatus 5 is an apparatus that measures an irregular shape (height) of a surface of an object. The measurement apparatus 5 measures the irregular shape by emitting, for example, laser light or ultrasonic waves to the surface of the object and detecting reflected waves thereof. In the present embodiment, the measurement apparatus 5 scans and measures a measurement region of a predetermined size on the surface of the object, thereby outputting the irregularity distribution information indicating the distribution of the irregular shapes in a two-dimensional region of the predetermined size to the information processing apparatus 1.

In the information processing system according to the present embodiment, for example, a first measurement for the chamber internal component is performed by the measurement apparatus 5 at a predetermined timing, such as when the substrate processing apparatus 3 is started up (at the first time point when the apparatus is introduced into a factory and the like) or when the deteriorated chamber internal component is replaced. Thereafter, the substrate processing apparatus 3 performs the etching processing on about several to several tens of substrates. This etching processing may be performed, for example, as the manufacture of an ordinary product, or may be performed through, for example, a test operation. After a certain degree of etching processing is performed, a second measurement for the chamber internal component is performed by the measurement apparatus 5.

The information processing apparatus 1 acquires the first and second measurement results obtained by the measurement apparatus 5 measuring the irregularity distribution information on the chamber internal component of the substrate processing apparatus 3. Based on the irregularity distribution information obtained in the first measurement and the second measurement, the information processing apparatus 1 calculates, as a change probability, a distribution of a probability of a change in the height of the irregularities caused by exposure of the chamber internal component to the plasma. Based on a time during which the etching processing is performed from the first measurement to the second measurement, and a virtual change amount sampled from the calculated change probability of the irregularities, the information processing apparatus 1 predicts the irregularity distribution of the chamber internal component after any time elapses. Based on the prediction result of the irregularity distribution, the information processing apparatus 1 calculates a time for which the irregularity distribution of the chamber internal component satisfies a predetermined condition, and predicts this time as the lifetime.

Accordingly, the information processing system according to the present embodiment can predict the lifetime of the chamber internal component at a relatively early stage after the substrate processing apparatus 3 is started up or after the component is replaced, and can provide the prediction result to the user such as the administrator of the substrate processing apparatus 3. The user can be expected to take measures such as preparing components for replacement in advance by grasping the lifetime of the chamber internal component in advance.

### Apparatus Configuration

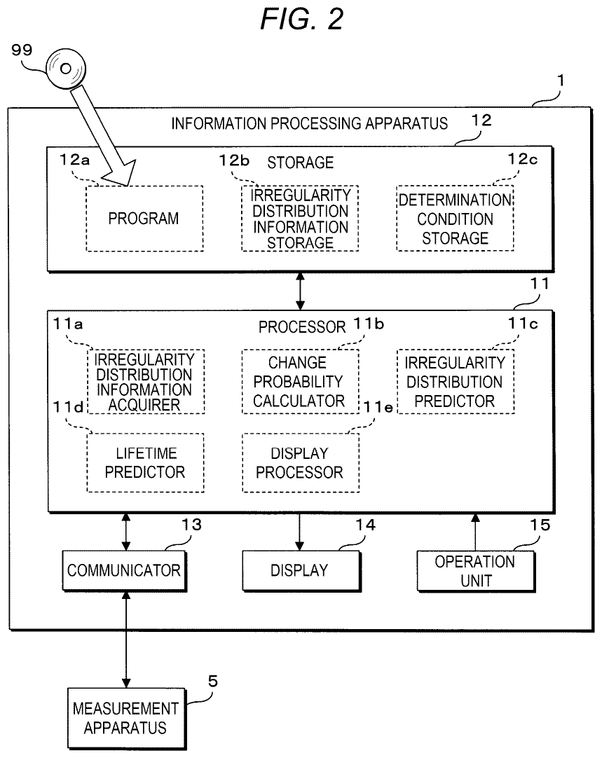

FIG. 2 is a block diagram illustrating a configuration example of the information processing apparatus 1 according to the present embodiment. The information processing apparatus 1 according to the present embodiment includes a processor 11, a storage 12, a communicator 13, a display 14, an operation unit 15, and the like (herein “processor” means the same as “controller circuitry”). In the present embodiment, an example will be described in which a process is performed by one information processing apparatus 1. Meanwhile, the process of the information processing apparatus 1 may be distributed and performed by a plurality of apparatuses.

The processor 11 is configured by using an arithmetic processing apparatus such as a central processing unit (CPU), a micro-processing unit (MPU), a graphics processing unit (GPU), or a quantum processor, a read only memory (ROM), a random access memory (RAM), and the like. The processor 11 reads and executes a program 12a stored in the storage 12, thereby performing various types of processing such as processing of acquiring the measurement result of irregularity distribution of the chamber internal component from the measurement apparatus 5, and processing of predicting the lifetime of the chamber internal component based on the acquired information. The processor/controller circuitry 11 can be programmable circuitry (e.g., embedded processor) or fixed circuitry (e.g., ASIC or PAL). In an exemplary embodiment, the processor/controller circuitry 11 can include one or more programmable processors/controllers.

The storage 12 is configured by using, for example, a large-capacity storage apparatus such as a hard disk. The storage 12 stores various types of programs to be executed by the processor 11 and various types of data necessary for the process of the processor 11. In the present embodiment, the storage 12 stores the program 12a to be executed by the processor 11. The storage 12 includes an irregularity distribution information storage 12b that stores the irregularity distribution information acquired from the measurement apparatus 5, and a determination condition storage 12c that stores a determination condition for predicting the lifetime of the chamber internal component.

In the present embodiment, the program (computer program, program product) 12a is provided in a form recorded on a recording medium 99 such as a memory card or an optical disc. The information processing apparatus 1 reads the program 12a from the recording medium 99, and stores the program 12a in the storage 12. However, for example, the program 12a may be written into the storage 12 during a manufacturing stage of the information processing apparatus 1. For example, as the program 12a, the information processing apparatus 1 may acquire those which are distributed by a remote server device or the like through communication. For example, the program 12a may be written into the storage 12 of the information processing apparatus 1 after a writing apparatus reads data recorded in the recording medium 99. The program 12a may be provided in the form of distribution through a network, or may be provided in the form recorded in the recording medium 99.

The irregularity distribution information storage 12b of the storage 12 stores the irregularity distribution information of the chamber internal component measured by the measurement apparatus 5, in association with, for example, identification information such as an apparatus ID of the substrate processing apparatus 3 in which the chamber internal component is provided or a component ID attached to the chamber internal component, time stamp information such as a date or time when a measurement is performed by the measurement apparatus 5, and information of a cumulative time during which the etching processing is performed using the chamber internal component. The identification information, the time stamp information, and the like are input by the user when a measurement is performed by the measurement apparatus 5. The information of the cumulative time may be input by the user, or may be calculated by the information processing apparatus 1 based on the above-described time stamp information and information such as an operation log of the substrate processing apparatus 3, or may be acquired, as the measured information, via communication with the substrate processing apparatus 3. The irregularity distribution information is, for example, information provided in a two-dimensional array form corresponding to the surface (two-dimensional plane) of the chamber internal component to be measured. A measured value of a height (depth) of the corresponding position is stored as each element of the two-dimensional array. That is, the irregularity distribution information is information of a planar distribution of the height (depth) of the chamber internal component.

The determination condition storage 12c of the storage 12 stores a determination condition for determining whether the chamber internal component reaches the lifetime, based on the irregularity distribution information of the chamber internal component measured by the measurement apparatus 5. In the present embodiment, the determination condition is predetermined by, for example, the designer or the administrator of the information processing system according to the present embodiment, as a threshold value for a variance σ calculated based on the irregularity distribution information. However, the determination condition may be appropriately changed by the user. The information processing apparatus 1 according to the present embodiment predicts future irregularity distribution information based on the results of two times of measurements performed on the chamber internal component, and predicts the lifetime of the chamber internal component by determining whether the lifetime has been reached based on the determination condition with respect to the predicted irregularity distribution information.

The communicator 13 is connected to the measurement apparatus 5 via a cable such as a communication line or a signal line, and transmits and receives data to and from the measurement apparatus 5 via these cables. In the present embodiment, the communicator 13 transmits, to the measurement apparatus 5, control information and the like supplied from the processor 11, and receives a measurement result of the irregularity distribution information transmitted from the measurement apparatus 5, and supplies the measurement result to the processor 11. In the present embodiment, the information processing apparatus 1 and the measurement apparatus 5 communicate with each other via the cable. However, the present disclosure is not limited thereto, and information may be transmitted and received via, for example, radio communication, or information may be transmitted and received via a recording medium such as a memory card.

The display 14 is configured by using a liquid crystal display or the like, and displays various images, characters, and the like based on the process of the processor 11. The information processing apparatus 1 can display, on the display 14, various types of information such as the irregularity distribution information of the chamber internal component acquired from the measurement apparatus 5, or the lifetime predicted for the chamber internal component.

The operation unit 15 receives a user operation and notifies the processor 11 of the received operation. For example, the operation unit 15 receives the user operation by an input device such as a mechanical button or a touch panel provided on a surface of the display 14. For example, the operation unit 15 may be an input device such as a mouse and a keyboard, and these input devices may be configured to be detachable from the information processing apparatus 1.

The storage 12 may be an external storage device connected to the information processing apparatus 1. The information processing apparatus 1 may be a multi-computer including a plurality of computers, or may be a virtual machine virtually constructed by software. In addition, the information processing apparatus 1 is not limited to the configuration described above, and does not need to include the display 14, the operation unit 15, and the like, for example.

In the information processing apparatus 1 according to the present embodiment, the processor 11 reads and executes the program 12a stored in the storage 12, thereby implementing an irregularity distribution information acquirer 11a, a change probability calculator 11b, an irregularity distribution predictor 11c, a lifetime predictor 11d, a display processor 11e, and the like as software-like functional units in the processor 11.

The irregularity distribution information acquirer 11a communicates with the measurement apparatus 5 by the communicator 13, thereby performing processing of acquiring the irregularity distribution information that is the measurement result of the irregularity distribution of the chamber internal component of the substrate processing apparatus 3 obtained by the measurement apparatus 5. For example, when the information processing apparatus 1 controls the operation of the measurement apparatus 5 and the like, the measurement apparatus 5 transmits the measurement result to the information processing apparatus 1 each time an irregularity of the chamber internal component is measured, and the irregularity distribution information acquirer 11a acquires the measurement result. For example, when the information processing apparatus 1 does not control the operation of the measurement apparatus 5 and the measurement apparatus 5 stores the information on the measurement result by itself, the irregularity distribution information acquirer 11a receives an input of the identification information such as the apparatus ID and the component ID from the user, and acquires a measurement result corresponding to the input identification information from the measurement apparatus 5. The irregularity distribution information acquirer 11a stores, in the irregularity distribution information storage 12b, the irregularity distribution information acquired from the measurement apparatus 5.

The change probability calculator 11b, based on the irregularity distribution information measured at the first measurement for the chamber internal component that is a target by the measurement apparatus 5, the second irregularity distribution information measured by the measurement apparatus 5 after, from the first measurement, a predetermined time during which the etching treatment is performed by the substrate processing apparatus 3 elapses or the number of times of the etching processing have been performed by the substrate processing apparatus 3, and the cumulative time during which the etching processing has been performed from the first measurement to the second measurement, performs processing of calculating, as the change probability, the distribution of the probability of the change in the height of the irregularities caused by the etching processing performed for the predetermined time for the chamber internal component.

As described above, the irregularity distribution information obtained from the measurement apparatus 5 is information of the planar distribution of the height (depth) of the surface of the chamber internal component, and is, for example, information given as a two-dimensional array. The change probability calculator 11b randomly selects one pixel of the two-dimensional array from the first irregularity distribution information, and extracts an amount of irregularities stored in the selected one pixel. Similarly, the change probability calculator 11b randomly selects one pixel of the two-dimensional array from the second irregularity distribution information, and extracts an amount of irregularities stored in the selected one pixel. The change probability calculator 11b calculates a change amount in irregularities by calculating a difference between the amount of irregularities extracted from the first irregularity distribution information and the amount of irregularities extracted from the second irregularity distribution information. The change probability calculator 11b repeats the extraction of the amount of irregularities and the calculation of the change amount, and obtains a probability distribution, in which the change amount of the irregularities appears, based on a plurality of change amounts thus obtained. In the present embodiment, the change probability calculator 11b calculates the probability distribution obtained in this way as the change probability of the irregularities. By sampling an appropriate change amount according to this probability distribution, a virtual change amount of irregularities from the first measurement to the second measurement can be obtained. Based on this change amount and the time from the first measurement to the second measurement, for example, a virtual change amount per hour can be obtained.

The irregularity distribution predictor 11c uses the change probability of the irregularities calculated by the change probability calculator 11b and the irregularity distribution information of the second measurement result to perform processing of predicting a future irregularity distribution of the chamber internal component. For example, irregularity distribution information after 50 hours from the second measurement is predicted, the irregularity distribution predictor 11c calculates the virtual change amount of the irregularities per hour of the etching processing based on the probability distribution calculated as the change probability of the irregularities, and calculates the virtual change amount of the irregularities for 50 hours by repeating the calculation. The irregularity distribution predictor 11c can predict the irregularity distribution information after 50 hours by applying a change amount in 50 hours to the second irregularity distribution information. Similarly, the irregularity distribution predictor 11c can predict irregularity distribution information after any time.

The lifetime predictor 11d performs processing of predicting the lifetime of the chamber internal component of the substrate processing apparatus 3, based on the future irregularity distribution information predicted by the irregularity distribution predictor 11c and the determination condition stored in advance in the determination condition storage 12c. In the present embodiment, the determination condition is set as the threshold value for the variance σ of the irregularity distribution information. For example, the lifetime predictor 11d causes the irregularity distribution predictor 11c to predict the irregularity distribution information every year, calculates the variance σ of the irregularity distribution information every year, and searches for how many years after the calculated variance σ exceeds a set threshold value, thereby predicting the lifetime of the chamber internal component. In the present example, an example in which the lifetime is predicted in units of one year has been described. However, for example, the lifetime may be predicted in units of one month, one week, or one day.

The display processor 11e performs processing of displaying various characters and images on the display 14. In the present embodiment, for example, the display processor 11e displays, as an image, the planar distribution of the irregularity distribution information acquired by the irregularity distribution information acquirer 11a from the measurement apparatus 5. In addition, the display processor 11e displays, as a graph, the frequency distribution generated based on the planar distribution. The display processor 11e displays, as a graph, a future frequency distribution predicted by the irregularity distribution predictor 11c. The display processor 11e displays information relating to the lifetime of the chamber internal component predicted by the lifetime predictor 11d.

### Configuration of Focus Ring

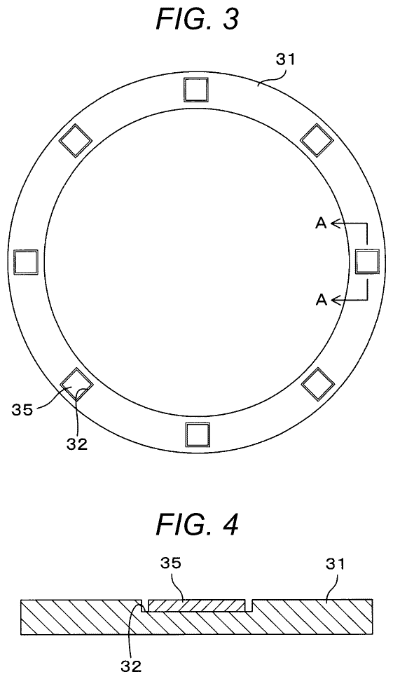

FIG. 3 is a schematic plan view illustrating a configuration example of a focus ring disposed in the substrate processing apparatus 3 in the information processing system according to the present embodiment. FIG. 4 is a schematic cross-sectional view taken along a line A-A in FIG. 3. A focus ring 31 disposed in the chamber of the substrate processing apparatus 3 is a plate-shaped member having a substantially annular shape in a plan view, and is made of a material such as silicon, quartz glass, SiC (silicon carbide), or ceramic. On one surface (upper surface) of the focus ring 31 used in the information processing system according to the present embodiment, substantially square recesses are formed at eight positions at substantially equal intervals in a circumferential direction as specimen holders 32.

Substantially square plate-shaped members are accommodated as specimens 35 and held on the eight specimen holders 32 formed in the focus ring 31. The specimens 35 are preferably formed of the same material as the focus ring 31. However, the specimens 35 may be formed of another material. The eight specimens 35 held on the eight specimen holders 32 may be all formed of the same material, or may be formed of different materials. A thickness of the specimen 35 is preferably the same as the depth of the specimen holder 32 or thinner than the depth of the specimen holder 32. However, the thickness of the specimen 35 may be thicker than the depth of the specimen holder 32.

In the present embodiment, the eight specimen holders 32 are provided in the focus ring 31. However, the present disclosure is not limited thereto, and the number of the specimen holders 32 may be seven or less or nine or more. It is not necessary for all of the eight specimen holders 32 provided in the focus ring 31 to hold the specimens 35, and it is sufficient for at least one specimen holder 32 to hold one specimen 35. The specimen holder 32 and the specimen 35 are substantially square. However, the present disclosure is not limited thereto, and various shapes such as a substantially rectangular shape, a substantially circular shape, and an appropriate polygonal shape may be adopted.

A stamp and the like for distinguishing front and back (up and down) may be formed on the specimen 35. In a case of forming a stamp and the like, it is preferable to form a stamp on a back surface (lower surface) of the specimen 35, that is, a surface that is not exposed to the outside in a state of being held by the specimen holder 32. For example, identification information such as an ID for uniquely identifying the specimen 35 may be formed as a stamp.

In the information processing system according to the present embodiment, the focus ring 31 is disposed in the chamber of the substrate processing apparatus 3 in a state where the specimens 35 are held in the specimen holders 32, and in this state, the processing such as etching is performed by the substrate processing apparatus 3. When the first and second measurements are performed by the measurement apparatus 5, the user removes the specimens 35 accommodated in the specimen holders 32 of the focus ring 31, and measures irregularities on the surfaces of the specimens 35 by the measurement apparatus 5. At this time, the user does not need to remove a main body of the focus ring 31 from the substrate processing apparatus 3. Accordingly, in the information processing system according to the present embodiment, by replacing the main body of the focus ring 31 with the specimens 35 held on the specimen holders 32 of the focus ring 31 being a measurement target of the measurement apparatus 5, it is possible to save time and effort for the user to remove the focus ring 31 from the substrate processing apparatus 3 for measurement, and it is expected to facilitate the measurement.

### Lifetime Prediction Processing

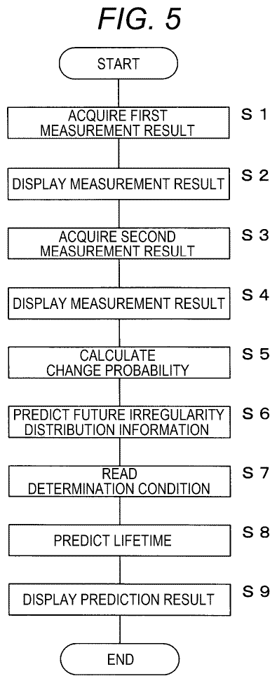

FIG. 5 is a flowchart illustrating an example of a procedure of lifetime prediction processing performed by the information processing apparatus 1 according to the present embodiment. In the information processing system according to the present embodiment, for example, the first measurement is performed by the measurement apparatus 5 as an initial measurement before the start of use of a new focus ring 31 by the substrate processing apparatus 3. At this time, the user sets the focus ring 31 (or the specimens 35 accommodated in the specimen holders 32 of the focus ring 31) in the measurement apparatus 5, and measures the distribution of the irregularities on the surface of the focus ring 31 by the measurement apparatus 5.

The irregularity distribution information acquirer 11a of the processor 11 of the information processing apparatus 1 according to the present embodiment communicates with the measurement apparatus 5 via the communicator 13, thereby acquiring a measurement result of a planar distribution relating to irregularities on the surface of the focus ring 31 of the substrate processing apparatus 3 that is a prediction target measured by the measurement apparatus 5 (step S1). In addition, at this time, for example, the irregularity distribution information acquirer 11a acquires, from the measurement apparatus 5, information such as the ID of the focus ring 31 and the date and time when the measurement is performed, and stores these acquired information and the measurement result in the irregularity distribution information storage 12b in association with each other. The information such as the ID of the focus ring 31 and the measurement date and time may be acquired not by being acquired from the measurement apparatus 5, but by receiving an information input from the user. For example, the display processor 11e of the processor 11 displays the planar distribution of the measurement result acquired in step S1 and the graph of the frequency distribution generated based on the planar distribution side by side, thereby displaying the first measurement result on the display 14 (step S2).

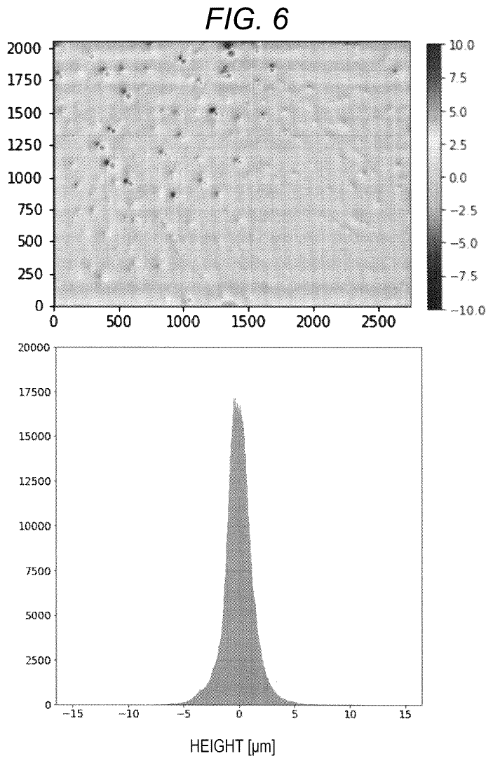

FIG. 6 is a schematic diagram illustrating a display example of the first measurement result. The graph illustrated in the upper part of FIG. 6 displays, as a two-dimensional image, the measurement result of the planar distribution relating to the irregularities on the surface of the focus ring 31 measured by the measurement apparatus 5. A vertical axis and a horizontal axis of the graph correspond to vertical and horizontal directions of the surface of the focus ring 31, and pixel values of the displayed two-dimensional image represent the heights (or depths) of the irregularities. The graph illustrated in the lower part of FIG. 6 is a graph in which a frequency distribution (histogram) relating to the pixel values of the two-dimensional image in the upper part is generated, and the horizontal axis represents height, and the vertical axis represents frequency (the number of pixels). In step S2, the information processing apparatus 1 displays the measurement result by, for example, displaying the two graphs side by side on the display 14.

After the first measurement is completed, the user operates the substrate processing apparatus 3 to which the focus ring 31 is disposed, and performs processing such as etching. At this time, the substrate processing apparatus 3 may perform etching processing in a normal manufacturing process targeting a substrate such as an actual semiconductor wafer, or may perform etching processing for measurement using a substrate for testing and the like. After the substrate processing apparatus 3 is operated for a predetermined time, the user removes the focus ring 31 (or the specimens 35 accommodated in the specimen holders 32 of the focus ring 31) attached to the substrate processing apparatus 3, sets the focus ring 31 in the measurement apparatus 5, and measures a second irregularity distribution by the measurement apparatus 5.

After an appropriate time elapses from the processing in step S2, the irregularity distribution information acquirer 11a of the information processing apparatus 1 communicates with the measurement apparatus 5 via the communicator 13, thereby acquiring the measurement result of the planar distribution relating to the irregularities on the surface of the focus ring 31 measured by the measurement apparatus 5 (step S3). At this time, for example, the irregularity distribution information acquirer 11a acquires information such as the ID of the focus ring 31, the date and time when the measurement is performed, and the cumulative time during which the etching processing is performed, and stores the acquired information and the measurement result in the irregularity distribution information storage 12b in association with each other. For example, the display processor 11e displays the planar distribution of the measurement result acquired in step S3 and the graph of the frequency distribution generated based on the planar distribution side by side, thereby displaying the second measurement result on the display 14 (step S4).

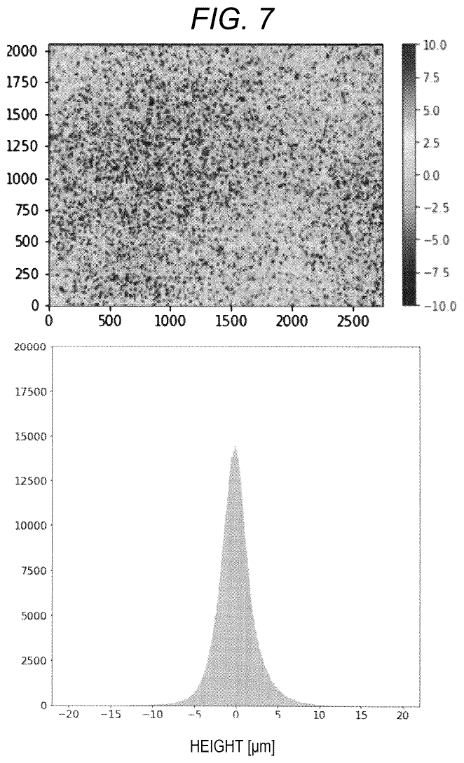

FIG. 7 is a schematic diagram illustrating a display example of the second measurement result, and is a result of an after-measurement after the etching processing is performed for about 10 hours from the first measurement illustrated in FIG. 6. Similar to FIG. 6, the upper part of FIG. 7 illustrates a graph of the planar distribution relating to the irregularities on the surface of the focus ring 31 relating to the second measurement, and the lower part of FIG. 7 illustrates a graph of the frequency distribution. In step S4, the information processing apparatus 1 displays the second measurement result by, for example, displaying the two graphs side by side on the display 14. Further, the information processing apparatus 1 may display the first measurement result and the second measurement result side by side. When the planar distribution of the first measurement result illustrated in the upper part of FIG. 6 is compared with the planar distribution of the second measurement result illustrated in the upper part of FIG. 7, it is understood that the irregularities on the surface increase in the second measurement result. When the frequency distribution of the first measurement result illustrated in the lower part of FIG. 6 is compared with the frequency distribution of the second measurement result illustrated in the lower part of FIG. 7, it can be understood that variations in the distribution of the height of the irregularities are widened in the second measurement result.

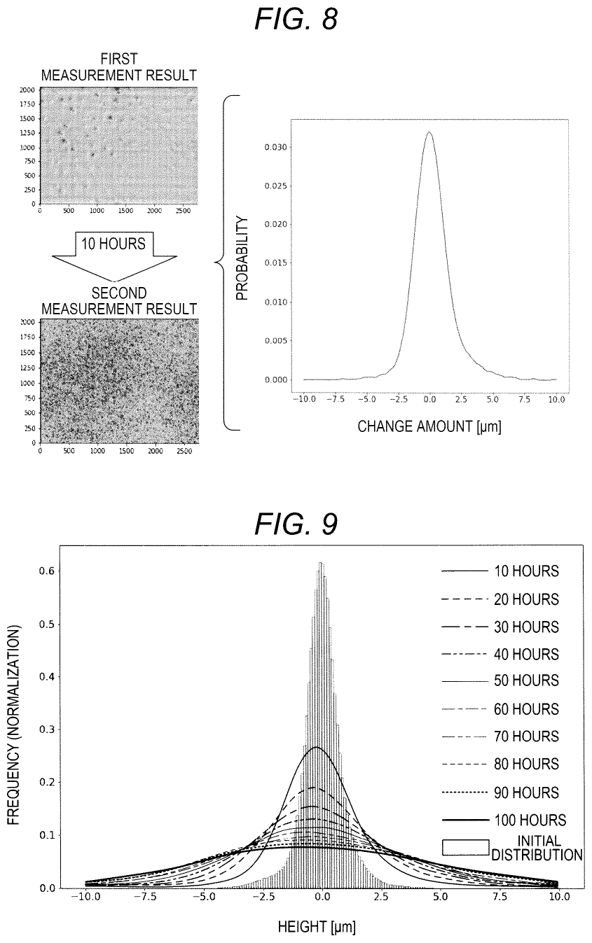

After displaying the measurement results in step S4, the change probability calculator 11b of the processor 11 of the information processing apparatus 1 calculates a change probability relating to the distribution of the irregularities on the surface of the focus ring 31 based on the irregularity distribution information of the first measurement result acquired in step S1 and the irregularity distribution information of the second measurement result acquired in step S3 (step S5). In the present embodiment, for example, the change probability calculator 11b extracts respective amounts of irregularities at random from the irregularity distribution information of the first measurement result and the irregularity distribution information of the second measurement result, and calculates a difference between the two extracted amounts of irregularities. The change probability calculator 11b repeats the calculation of the difference between the amounts of irregularities, and calculates the probability distribution, in which the change amount of the irregularities appears, based on a plurality of change amounts thus obtained. FIG. 8 is a schematic diagram illustrating the calculation of the change amount by the information processing apparatus 1. In the left part of FIG. 8, an image of the planar distribution of the first measurement result and an image of the planar distribution of the second measurement result are illustrated side by side in an up-down direction. The right part of FIG. 8 is a graph of the probability distribution, in which the change amount of the irregularities appears, calculated based on the first measurement result and the second measurement result. In the present example, it can be predicted that the change in irregularities illustrated by the illustrated probability distribution occurs at each point on the surface of the specimen 35 that is the measurement target by performing the etching processing for 10 hours by the substrate processing apparatus 3. The change probability calculator 11b may use the probability distribution of the change amount per 10 hours as a calculation result of step S5, or may further calculate a change amount of 1/10 of the change amount per 10 hours and use the probability distribution of the change amount per hour as the calculation result of the change probability of step S5.

After calculating the change probability in step S5, the irregularity distribution predictor 11c of the information processing apparatus 1 predicts future irregularity distribution information when the etching processing is performed by the substrate processing apparatus 3, based on the change probability calculated in step S5 and the second measurement result acquired in step S3 (step S6). For example, the irregularity distribution predictor 11c can obtain a virtual change amount per 10 hours by sampling an appropriate change amount according to the probability illustrated in the probability distribution calculated as the change probability in step S5, and can obtain a virtual change amount per hour by multiplying by 1/10. For example, the irregularity distribution predictor 11c can predict the irregularity distribution information after 20 hours by causing a change corresponding to the virtual change amount per 10 hours with respect to the second irregularity distribution information (for example, irregularity distribution information after 10 hours). The irregularity distribution predictor 11c can predict the irregularity distribution information after 30 hours based on the irregularity distribution information after 20 hours and the virtual change amount per 10 hours, and can predict the irregularity distribution information after 40 hours based on the irregularity distribution information after 30 hours and the virtual change amount per 10 hours. Similarly, the irregularity distribution predictor 11c predicts irregularity distribution information every 10 hours, for example, until the predetermined time is reached.

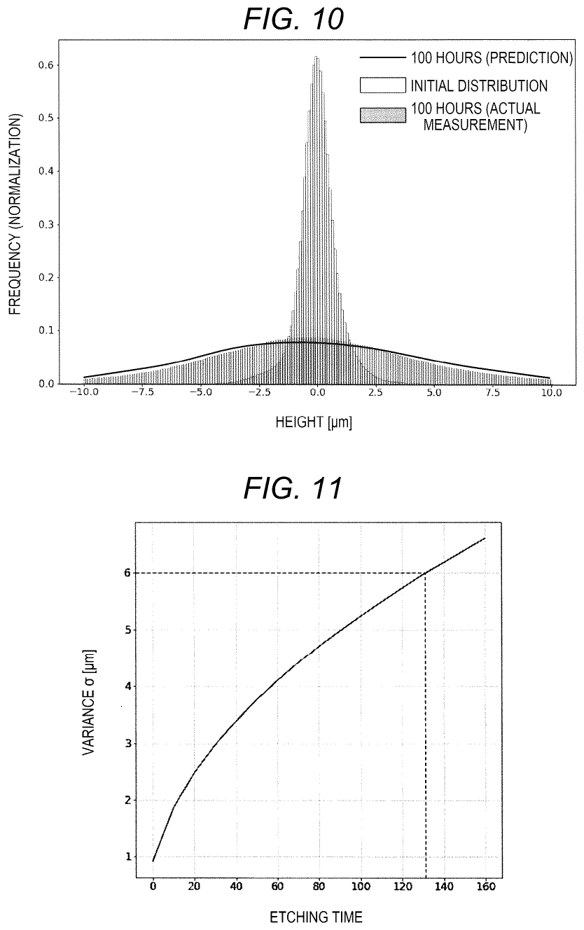

FIG. 9 is a schematic diagram illustrating an example of prediction of the irregularity distribution information by the information processing apparatus 1, and is a graph illustrating heights of irregularities and appearance frequencies (frequencies) as frequency distributions, based on the irregularity distribution information at each time. In the graph illustrated in FIG. 9, the horizontal axis represents the height [μm] of the irregularity, and the vertical axis represents the frequency, but the frequency of the vertical axis represents a normalized value. From the prediction result illustrated in FIG. 9, it can be understood that the widening (variation) of the distribution of irregularities increases as a cumulative time for performing the etching increases. FIG. 10 is a schematic diagram illustrating examples of a predicted value and a measured value of a frequency distribution, and is a graph obtained by superimposing the predicted value and the measured value of the frequency distribution after 100 hours with respect to the initial distribution. The measured value illustrated in FIG. 10 is obtained by measuring, using the measurement apparatus 5, the irregularities of the focus ring 31 after the substrate processing apparatus 3 actually performs the etching processing and the cumulative time thereof reaches 100 hours, and generating a frequency distribution based on a planar distribution obtained as a measurement result. As illustrated in FIG. 10, it can be understood that the frequency distribution of the irregularities after 100 hours predicted by the information processing apparatus 1 according to the present embodiment is an accurate prediction of the frequency distribution obtained through the actual measurement by the measurement apparatus 5.

After predicting the irregularity distribution information at a plurality of future time points in step S6, the lifetime predictor 11d of the information processing apparatus 1 reads the determination condition for predicting the lifetime of the focus ring 31 from the determination condition storage 12c of the storage 12 (step S7). In the present embodiment, the determination condition is predetermined by, for example, the designer or the administrator of the present system and stored in the determination condition storage 12c as a threshold value with respect to the variance σ for information on a plurality of heights included in the irregularity distribution information. The lifetime predictor 11d reads the threshold value stored in the determination condition storage 12c.

Next, the lifetime predictor 11d predicts the lifetime of the focus ring 31 based on the determination condition read in step S7 (step S8). At this time, the lifetime predictor 11d calculates the values of the variances σ for the irregularity distribution information at the plurality of time points predicted in step S6. The lifetime predictor 11d compares the calculated variances σ with the threshold value of the read determination condition, and sets the shortest time during which the variance σ exceeds the threshold value (or the longest time during which the variance σ does not exceed the threshold value) as the lifetime of the focus ring 31. FIG. 11 is a schematic diagram illustrating an example of lifetime prediction by the information processing apparatus 1. FIG. 11 is a graph in which the horizontal axis represents the etching time and the vertical axis represents the variance σ. The time series change of the variance σ of the frequency distribution of the irregularities predicted every 10 hours is illustrated as a broken line.

As illustrated in the drawing, the variance σ relating to the distribution of the irregularities of the focus ring 31 increases as the etching time increases. In the present example, the threshold value that serves as a reference for determining the lifetime for the variance σ is set to σ=6, and the lifetime predictor 11d predicts the lifetime of the focus ring 31 as the etching time (in the present example, 130 hours) at which the variance σ exceeds the threshold value. In the present example, the variance σ every 10 hours is calculated, and the lifetime predictor 11d predicts the lifetime in units of 10 hours. For example, when the time during which the variance σ exceeds the threshold value is a time between 120 hours and 130 hours, the lifetime predictor 11d, for example, discards a time less than 10 hours and sets 120 hours as the lifetime. However, the lifetime predictor 11d may set 130 hours as the lifetime by, for example, rounding or rounding up the time of less than 10 hours, or may calculate the lifetime in units of one hour by an arithmetic operation such as linear interpolation.

After predicting the lifetime of the focus ring 31 in step S8, the display processor 11e of the information processing apparatus 1 displays the prediction result of the lifetime on the display 14 (step S9), and ends the processing. At this time, the display processor 11e can display, in addition to a message notifying the predicted lifetime of the focus ring 31, the graph of the prediction result of the frequency distribution illustrated in FIG. 9 and the graph illustrating the change of the variance σ illustrated in FIG. 11 side by side. The display processor 11e may display the prediction result of the lifetime in any form.

### Summary

In the information processing system according to the present embodiment having the configuration described above, the information processing apparatus 1 acquires the distribution information measured by the measurement apparatus 5 with respect to the irregularities on the surface of the chamber internal component at the first time point, such as the time point when the focus ring 31 (chamber internal component) is started to be used. Thereafter, the information processing apparatus 1 acquires the distribution information measured by the measurement apparatus 5 with respect to the irregularities on the surface of the chamber internal component at the second time point after the substrate processing such as the etching processing is performed from the first time point. Based on the acquired distribution information at the first time point and distribution information at the second time point, the information processing apparatus 1 predicts the distribution information of irregularities of the chamber internal component at the time point after the substrate processing is performed from the second time point. Accordingly, the information processing system according to the present embodiment can be expected to predict the state of the chamber internal component of the substrate processing apparatus 3 from the measurement results of the irregularities at two time points of the first time point and the second time point.

In the information processing system according to the present embodiment, the information processing apparatus 1 predicts the lifetime of the chamber internal component based on the predicted distribution information of the irregularities of the chamber internal component. Accordingly, the information processing system according to the present embodiment can be expected to support the operation of the substrate processing apparatus 3 by the user, such as the user examining a schedule for replacing the chamber internal component of the substrate processing apparatus 3 based on the predicted lifetime.

In the information processing system according to the present embodiment, the information processing apparatus 1 calculates the change probability of the irregularities of the chamber internal component due to the substrate processing, based on the distribution information at the first time point and the distribution information at the second time point. Based on the calculated change probability, the information processing apparatus 1 predicts the distribution information of the irregularities of the chamber internal component at a time point after the second time point, for example, by changing the distribution information at the second time point according to the calculated change probability. Accordingly, the information processing system according to the present embodiment can be expected to accurately predict the state of the chamber internal component of the substrate processing apparatus 3 based on the change probability, from the measurement results of the irregularities at two time points of the first time point and the second time point.

In the information processing system according to the present embodiment, the information processing apparatus 1 calculates a difference between a height of an irregularity appropriately extracted from the irregularity distribution information at the first time point and a height of an irregularity appropriately extracted from the irregularity distribution information at the second time point, and calculates the change probability of the irregularities by repeating the calculation of the difference, and predicts the future irregularity distribution information by changing the irregularity distribution information at the second time point according to the change probability. Accordingly, the information processing system according to the present embodiment can be expected to predict the variation in the irregularities of the chamber internal component and to predict the lifetime.

In the information processing system according to the present embodiment, the specimen holder 32 that holds the specimen 35 for acquiring the distribution information is provided in the focus ring 31 (chamber internal component) of the substrate processing apparatus 3. The information processing apparatus 1 acquires, as the distribution information of the irregularities of the focus ring 31, information obtained by measuring the distribution of the irregularities of the specimen 35 by the measurement apparatus 5. Accordingly, the information processing system according to the present embodiment can measure the irregularities on the specimen instead of the chamber internal component without removing the chamber internal component from the substrate processing apparatus 3 in order to measure the irregularities by the measurement apparatus 5. Therefore, it can be expected that the measurement can be facilitated.

### Second Embodiment

In an information processing system according to a second embodiment, a sensor that measures the irregularity distribution information of the focus ring 31 is provided in the substrate processing system that includes a plurality of substrate processing apparatuses 3. In other words, in the information processing system according to the second embodiment, the substrate processing apparatus 3 and the measurement apparatus 5 are integrally provided. Further, in the information processing system according to the second embodiment, the substrate processing system performs prediction processing performed by the information processing apparatus 1 described above. That is, in the information processing system according to the second embodiment, the substrate processing system, which includes the substrate processing apparatus 3, and the information processing apparatus 1 are integrally provided.

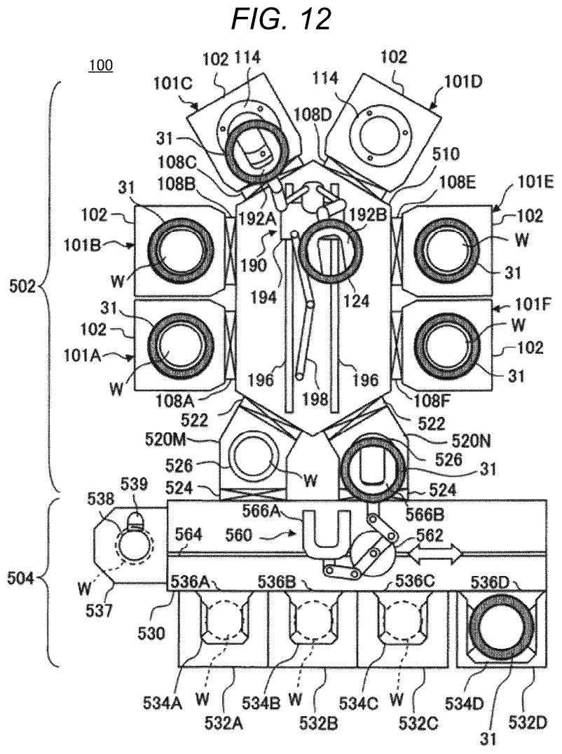

FIG. 12 is a schematic diagram illustrating a configuration example of the substrate processing system according to the second embodiment. The illustrated substrate processing system 100 is a so-called cluster tool type substrate processing apparatus in which a plurality of plasma processing apparatuses (substrate processing apparatuses 3) are connected to a decompressible common transfer chamber.

The substrate processing system 100 according to the second embodiment includes a vacuum processing unit 502, in which a plurality of (here, six) plasma processing apparatuses 101A to 101F are connected around a common transfer chamber 510 via gate valves 108A to 108F, and a transfer unit 504 that transfers a wafer W into and out of the vacuum processing unit 502. The common transfer chamber 510 is configured to control the inside thereof to a predetermined vacuum pressure, and a transfer arm 190 is disposed in the common transfer chamber 510. Accordingly, the wafer W and the focus ring 31 can be transferred between the common transfer chamber 510 and each of the plasma processing apparatuses 101A to 101F in a pressure-reduced atmosphere.

The transfer arm 190 includes two picks 192A and 192B, and can handle two wafers W or two focus ring 31 at a time. The transfer arm 190 is rotatably supported by a base 194. The base 194 is slidable by, for example, a slide driving motor on a guide rail 196 disposed from a base end side to a tip end side in the common transfer chamber 510. For example, a flexible arm 198 through which a wiring of a motor for turning the arm and the like passes is connected to the base 194.

A case where the substrate processing system 100 illustrated in FIG. 12 includes six plasma processing apparatuses 101 is exemplified. However, the present disclosure is not limited to this example, and the substrate processing system 100 may include five or less plasma processing apparatuses 101. The substrate processing system 100 illustrated in FIG. 12 may be provided with at least one plasma processing apparatus 101 that requires replacement of the focus ring 31, and may be provided with another processing apparatus (for example, a heat processing apparatus and a film forming apparatus) (herein “film” means the same as “layer”).

One ends of first and second load-lock chambers 520M and 520N are connected to the periphery of the common transfer chamber 510 via gate valves (vacuum pressure side gate valves) 522, respectively, and the other ends of the first and second load-lock chambers 520M and 520N are connected to a transfer chamber 530 forming the transfer unit 504 via gate valves (atmospheric pressure side gate valves) 524, respectively.

The first and second load-lock chambers 520M and 520N have a function of temporarily holding the wafer W or the focus ring 31, and passing the wafer W or the focus ring 31 to the common transfer chamber 510 after being adjusted to the pressure-reduced atmosphere, and passing the wafer W or the focus ring 31 to the transfer chamber 530 of the transfer unit 504 after being adjusted to an atmospheric pressure atmosphere. Transfer tables 526 on which the wafer W and the focus ring 31 can be placed are provided in the first and second load-lock chambers 520M and 520N, respectively.

According to such a vacuum processing unit 502, a processing chamber 102 of each of the first and second load-lock chambers 520M and 520N and the plasma processing apparatuses 101A to 101F can be accessed by sliding the transfer arm 190 along the guide rail 196. For example, when the transfer arm 190 accesses the first and second load-lock chambers 520M and 520N and the processing chamber 102 of each of the plasma processing apparatuses 101A and 101F disposed to face each other, the transfer arm 190 is positioned near the base end side of the common transfer chamber 510 along the guide rail 196.

When the transfer arm 190 accesses the processing chamber 102 of each of the other four plasma processing apparatuses 101B to 101E, the transfer arm 190 is positioned near the tip end side of the common transfer chamber 510 along the guide rail 196. Accordingly, all the processing chambers 102 and the first and second load-lock chambers 520M and 520N, which are connected to the common transfer chamber 510, can be accessed by one transfer arm 190.

In the present example, the case where one transfer arm 190 is slidably provided has been described as an example. However, the present disclosure is not limited thereto, and for example, one transfer arm 190 may be rotatably fixed toward the base end side and the tip end side of the common transfer chamber 510, respectively. The number of picks of the transfer arm 190 is not limited to two, and may be, for example, only one.

Next, a configuration example of the transfer unit 504 will be described. The transfer unit 504 is implemented by the box-shaped transfer chamber 530. The inside of the transfer chamber 530 is an atmospheric pressure atmosphere, and an inert gas such as an N₂ gas or a clean air is circulated. A plurality of cassette stages 532A to 532D are disposed side by side on the transfer chamber 530. Cassette containers 534A to 534C for accommodating the wafers W are set in these cassette stages 532A to 532C. Three load ports 536A to 536C serving as charging ports for the wafers W are provided in a sidewall of the transfer chamber 530 to correspond to the cassette stages 532A to 532C, respectively.

In the drawing, for example, the three cassette containers 534A to 534C can be placed on the cassette stages 532A to 532C, respectively. However, the number of cassette stages and the cassette containers is not limited thereto, and for example, one or two cassette stages and cassette containers or four or more may be provided.

In each of the cassette containers 534A to 534C, at least one lot (for example, 25 wafers W) or more can be placed and accommodated in multiple stages at an equal pitch, and the inside thereof has, for example, a sealed structure filled with an N₂ gas atmosphere.

A cassette container 534D, in which the focus ring 31 is accommodated, is set on the cassette stage 532D. As a charging port of the focus ring 31, a load port 536D is provided to correspond to the cassette stage 532D. The cassette container 534D accommodates the focus ring 31.

The transfer chamber 530 includes an orienter (pre-alignment stage) 537 serving as a positioning apparatus for the wafer W. The orienter 537 includes, for example, a rotation stage 538 and an optical sensor 539 that optically detects a peripheral edge of the wafer W, and performs alignment by detecting an orientation flat, a notch, and the like of the wafer W.

The transfer chamber 530 accommodates the cassette containers 534A to 534D, the orienter 537, and a transfer arm 560 for transferring the wafers W or the focus rings 31 into and out of the first and second load-lock chambers 520M and 520N. The transfer arm 560 is fixed on a base 562, and the base 562 is slidable on a guide rail 564 provided along a longitudinal direction in the transfer chamber 530 by, for example, a linear motor driving mechanism. The transfer arm 560 may be, for example, a double-arm mechanism including two picks 566A and 566B as illustrated in the drawing, or may be a single-arm mechanism including one pick.

According to the substrate processing system 100 having such a configuration, for example, the wafers W can be taken out from the predetermined cassette containers 534A to 534C, transferred to the desired plasma processing apparatuses 101A to 101F, and subjected to plasma processing such as etching. For example, when the wafer W in the cassette container 534A is subjected to the plasma processing by the plasma processing apparatus 101A, first, when the wafer W is taken from the cassette container 534A into the transfer chamber 530 by the transfer arm 560, the wafer W is transferred into the orienter 537 and aligned. Next, the wafer W is transferred out of the orienter 537 by the transfer arm 560 and transferred into the load-lock chamber 520N adjusted to the atmospheric pressure atmosphere.

Subsequently, when the load-lock chamber 520N is adjusted to the pressure-reduced atmosphere, the wafer W is transferred out by the transfer arm 190 on the other side, taken into the common transfer chamber 510, and transferred into the processing chamber 102 of the plasma processing apparatus 101A. Accordingly, the plasma processing apparatus 101A executes the plasma processing on the wafer W.

When the plasma processing by the plasma processing apparatus 101A is completed, the wafer W processed is transferred out from the processing chamber 102 and transferred into the load-lock chamber 520M adjusted to the pressure-reduced atmosphere by the transfer arm 190. When the load-lock chamber 520N is adjusted to the atmospheric pressure atmosphere, the wafer W is transferred out by the transfer arm 560 and returned to the original cassette container 534A.

When the focus ring 31 is replaced, the focus ring 31 is transferred substantially in the same manner as the wafer W. For example, when the focus ring 31 of the plasma processing apparatus 101C is replaced, a new focus ring 31 is taken out from the cassette container 534D by the transfer arm 560 and transferred into the load-lock chamber 520M. Subsequently, the new focus ring 31 is taken out from the load-lock chamber 520M after the pressure adjustment by the pick 192A on one side of the transfer arm 190, and slides to the position immediately before the plasma processing apparatus 101C.

Next, the used focus ring 31 is received from a lifter pin of a susceptor 114 by the pick 192B on the other side of the transfer arm 190, and is taken out from the plasma processing apparatus 101C. After this operation, the new focus ring 31 is continuously transferred to the lifter pin of the susceptor 114 by the pick 192A on one side. The used focus ring 31 is returned to an original cassette container 534 through the load-lock chamber 520M.

When a new focus ring 31 is transferred into the plasma processing apparatus 101C, the new focus ring 31 is placed on a focus ring placement surface by lowering the new focus ring by the lifter pin of the susceptor 114.

Although the case where the focus ring 31 is accommodated in the cassette container 534D has been described above, the present disclosure is not necessarily limited thereto. Since the replacement of the focus ring is not frequently performed as in the case of the wafer W, for example, instead of being accommodated in the cassette container 534D, a stage for the one or more focus rings 31 may be provided in the orienter 537. In this case, the focus ring 31 may be set to the stage of the orienter 537, and the focus ring 31 may be transferred out by the transfer arm 560 and transferred to the desired plasma processing apparatuses 101A to 101F. When it is necessary to replace the focus ring 31, an operator may place the focus ring 31 directly on either the picks 566A or 566B of the transfer arm 560.

In the information processing system according to the second embodiment, in the substrate processing system 100 provided with a transfer mechanism illustrated in FIG. 12, sensors for measuring irregularity distribution information of the focus rings 31 are provided, for example, on the picks 192A and 192B of the transfer arm 190 and/or the picks 566A and 566B of the transfer arm 560. The substrate processing system 100 illustrated in FIG. 12 includes four picks of a transfer arm, and the sensor is mounted on at least one of the picks. In the following description, it will be assumed that the pick 192A of the transfer arm 190 is provided with a sensor.

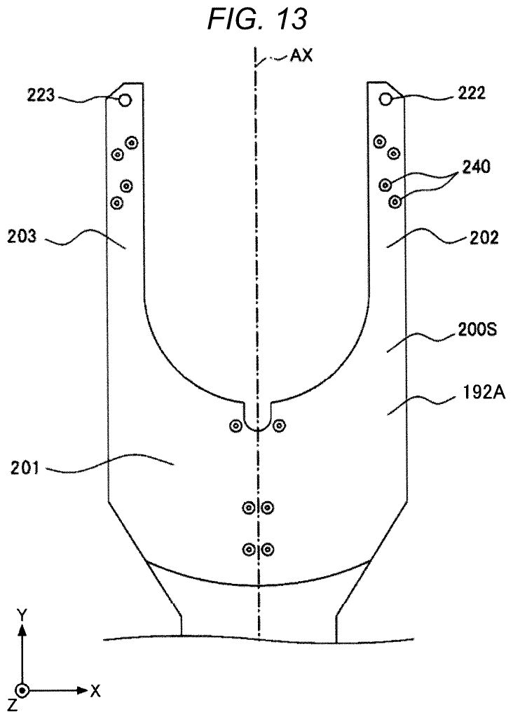

FIG. 13 is a schematic diagram illustrating a configuration example of the pick 192A of the transfer arm 190 of the substrate processing system 100 according to the second embodiment. In the drawing, an XYZ orthogonal coordinate system may be set for convenience of description. With respect to a coordinate axis perpendicular to a paper plane of the drawing, a cross mark in a circle of the coordinate axis indicates that a back direction is positive with respect to the paper plane, and a black circle in the circle indicates that a front side is positive with respect to the paper plane. However, the coordinate system is determined for description, and a posture of the pick 192A and the like is not limited thereto.

In the present disclosure, an X axis and a Y axis are axes in parallel with the placement surface of the pick 192A, unless otherwise described. The Y axis is an axis in a direction in which a tip end portion of the pick 192A extends. The X axis is an axis perpendicular to the Y axis. The Z axis is an axis in a direction perpendicular to the X axis and the Y axis. The Z-axis direction may be referred to as a vertical direction.

The pick 192A of the transfer arm 190 has a substantially U-shape in a plan view. The pick 192A is symmetrical in the plan view with respect to a central axis AX passing through a center in an X axis direction. The pick 192A has a base portion 201, a tip end portion 202, and a tip end portion 203. Each of the tip end portion 202 and the tip end portion 203 is provided to extend in a +Y axis direction from the base portion 201. Each of the tip end portion 202 and the tip end portion 203 has a substantially rectangular shape in the plan view that is short in the X axis direction and long in the Y axis direction. The tip end portion 202 is provided to be separated from the tip end portion 203 in the +X axis direction. The pick 192A is made of, for example, ceramic.

In the pick 192A, on a placement surface 200S, on which either a substrate or a consumable component is placed, a plurality of pads 240 for protecting the substrate from coming into contact with the placement surface 200S are provided. The pick 192A includes sensors 222 and 223 for measuring the irregularity distribution information on a back surface of the placement surface 200S. The sensor 222 is provided at a tip end of the tip end portion 202 on the +Y side in the Y axis direction. The sensor 223 is provided at a tip end of the tip end portion 203 on the +Y side in the Y axis direction.

As the sensors 222 and 223, various sensors such as an optical sensor, a camera (image sensor), a distance sensor, or a reflection-type light intensity sensor may be adopted. The sensors 222 and 223 measure, for example, distribution information of irregularities on the surface of the focus ring 31 present below the pick 192A.

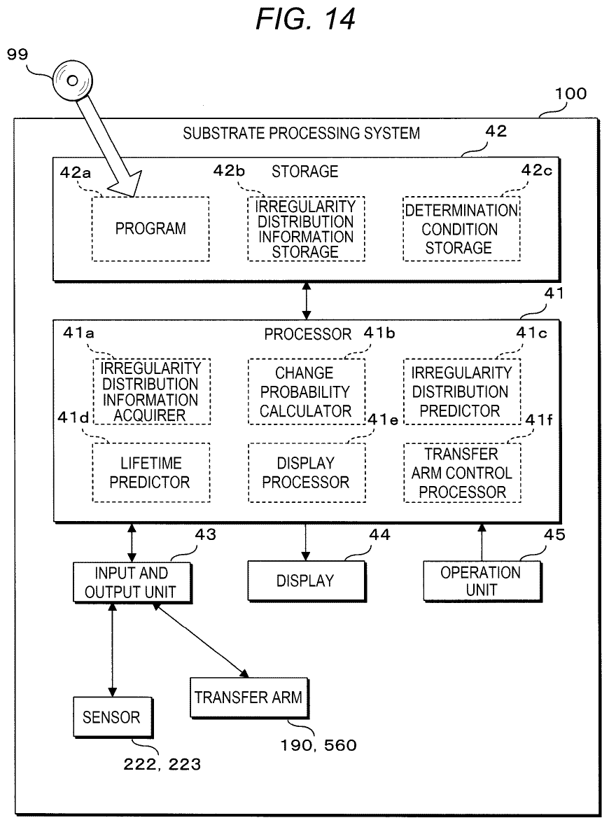

FIG. 14 is a block diagram illustrating a configuration example of the substrate processing system 100 according to the second embodiment. The substrate processing system 100 according to the second embodiment includes a processor 41, a storage 42, an input and output unit 43, a display 44, an operation unit 45, and the like. Functional blocks such as the processor 41, the storage 42, the input and output unit 43, the display 44, and the operation unit 45 are provided in a control device, an information processing apparatus, and the like that controls the operations of the various hardware units illustrated in FIG. 12. FIG. 14 illustrates the functional blocks relating to the prediction of the irregularity distribution of the focus ring 31 performed by the substrate processing system 100. Other functional blocks are omitted from the drawing. Since the configuration of the substrate processing system 100 illustrated in FIG. 14 is the same as the configuration of the information processing apparatus 1 illustrated in FIG. 2, the components of the substrate processing system 100 will be described briefly, and a detailed description thereof will be omitted.

The processor 41 is implemented by using, for example, an arithmetic processing apparatus such as a CPU or an MPU, a ROM, and a RAM. The storage 42 is implemented by using, for example, a large-capacity storage apparatus such as a hard disk, stores a program 42a executed by the processor 41, and includes an irregularity distribution information storage 42b and a determination condition storage 42c, similarly to the information processing apparatus 1 according to the first embodiment. The display 44 is implemented by using a liquid crystal display and the like. The operation unit 45 receives the user operation by an input device such as a mechanical button or a touch panel provided on a surface of the display 44.

The input and output unit 43 is connected to, for example, the hardware units such as the sensors 222 and 223 and the transfer arm 190 provided in the substrate processing system 100 via signal lines and the like, and transmits and receives signals to and from these hardware units. In the substrate processing system 100 according to the second embodiment, the input and output unit 43 receives an input of irregularity distribution information (or information that serves as a basis for the information) measured by the sensors 222 and 223, and supplies the input to the processor 41. The input and output unit 43 outputs a control signal to the transfer arm 190 in response to a command from the processor 41, so as to control the transfer of the wafer or the focus ring 31 performed by the transfer arm 190.

In the substrate processing system 100 according to the second embodiment, the processor 41 reads and executes the program 42a stored in the storage 42, thereby implementing an irregularity distribution information acquirer 41a, a change probability calculator 41b, an irregularity distribution predictor 41c, a lifetime predictor 41d, a display processor 41e, a transfer arm control processor 41f, and the like as software-like functional units in the processor 41.

The irregularity distribution information acquirer 41a receives signals output from the sensors 222 and 223 by the input and output unit 43, thereby performing processing of acquiring irregularity distribution information that is a measurement result of an irregularity distribution of a chamber internal component. In the second embodiment, since the sensors 222 and 223 are provided in the picks 192A and 192B of the transfer arm 190, it is necessary to move the transfer arm 190 for measurement, and this movement control is performed by the transfer arm control processor 41f. In the present embodiment, the irregularity distribution information acquirer 41a acquires the first measurement result and the second measurement result after the predetermined time elapses, and stores the acquired irregularity distribution information in the irregularity distribution information storage 42b. The first measurement of the irregularity distribution may be performed by a measurement apparatus different from the substrate processing system 100, but in this case, the irregularity distribution information acquirer 41a may acquire a measurement result obtained by the measurement apparatus via communication, a recording medium, and the like.

Processing performed by the change probability calculator 41b, the irregularity distribution predictor 41c, the lifetime predictor 41d, and the display processor 41e of the substrate processing system 100 is substantially the same as the change probability calculator 11b, the irregularity distribution predictor 11c, the lifetime predictor 11d, and the display processor 11e of the information processing apparatus 1 illustrated in FIG. 2.

The transfer arm control processor 41f controls the operations of the transfer arms 190 and 560 provided in the substrate processing system 100. In the present embodiment, when the sensors 222 and 223 measure the irregularity distribution of the surface of the focus ring 31, the transfer arm control processor 41f causes the pick 192A of the transfer arm 190 to move to a position above the focus ring 31 to be measured, and causes the sensors 222 and 223 provided on the lower surface of the pick 192A to face a predetermined measurement location of the focus ring 31. When it is determined that replacement of the focus ring 31 is necessary based on the prediction result from the lifetime predictor 41d, the transfer arm control processor 41f controls the transfer arm 190 to remove the focus ring 31 to be replaced from the processing chamber 102 and place a new focus ring 31 in the processing chamber 102.

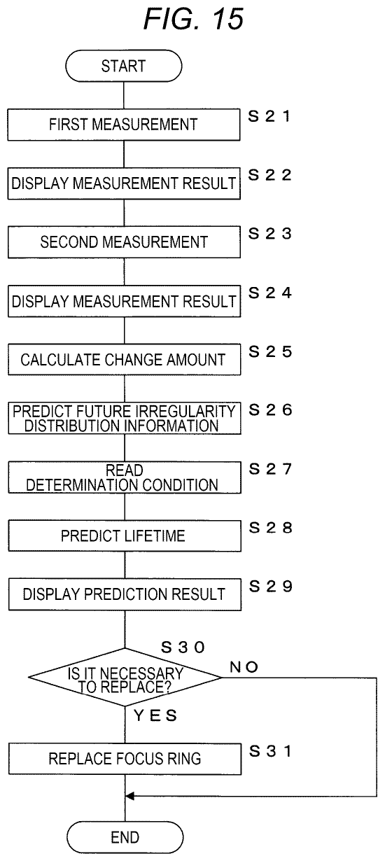

FIG. 15 is a flowchart illustrating an example of a procedure of lifetime prediction processing performed by the substrate processing system 100 according to the second embodiment. In the processor 41 of the substrate processing system 100 according to the second embodiment, the transfer arm control processor 41f causes the transfer arm 190 to move to the processing chamber 102 and the like in which the focus ring 31 to be measured is placed, and performs measurements by the sensors 222 and 223, and the irregularity distribution information acquirer 41a acquires a measurement result, thereby performing the first measurement of the irregularity distribution information (step S21). The display processor 41e of the processor 41 displays the first measurement result obtained in step S21 on the display 44 (step S22).

After the first measurement is completed, the substrate processing system 100 performs substrate processing such as etching over a predetermined time. Thereafter, similar to the first measurement, the processor 41 performs the second measurement of the irregularity distribution information using the sensors 222 and 223 of the transfer arm 190 (step S23). The display processor 41e displays the second measurement result on the display 44 (step S24).

After displaying the measurement result in step S24, the change probability calculator 41b of the processor 41 calculates a change probability relating to the distribution of the irregularities on the surface of the focus ring 31 based on the irregularity distribution information of the first measurement result acquired in step S21 and the irregularity distribution information of the second measurement result acquired in step S23 (step S25). The irregularity distribution predictor 41c of the processor 41 predicts future irregularity distribution information based on the change probability calculated in step S25 and the second measurement result acquired in step S23 (step S26).

Next, the lifetime predictor 41d of the processor 41 reads a determination condition for predicting the lifetime of the focus ring 31 from the determination condition storage 42c of the storage 42 (step S27). The lifetime predictor 41d predicts the lifetime of the focus ring 31 based on the determination condition read in step S27 (step S28). The display processor 41e of the processor 41 displays the prediction result of the lifetime in step S28 on the display 44 (step S29).

The lifetime predictor 41d determines whether it is necessary to replace the focus ring 31 based on the prediction result of the lifetime (step S30). For example, when a remaining lifetime of the focus ring 31 predicted in step S28 is less than a predetermined threshold value, the lifetime predictor 41d can determine that it is necessary to replace the focus ring 31.

When it is necessary to replace the focus ring 31 (S30: YES), the display processor 41f of the processor 41 performs control processing of replacing the focus ring 31 (step S31), and ends the processing. When it is not necessary to replace the focus ring 31 (S30: NO), the processor 41 ends the processing.

Since the other configurations of the information processing system according to the second embodiment are the same as those of the information processing system according to the first embodiment, the same reference numerals are given to the same locations, and a detailed description thereof will be omitted.

### Third Embodiment

In an information processing system according to a third embodiment, a sensor that measures the irregularity distribution information of the focus ring 31 is provided at a predetermined measurement location provided in the substrate processing system 100. For example, any one of the six processing chambers 102 provided in the substrate processing system 100 having the configuration illustrated in FIG. 12 is used as a measurement chamber for irregularity distribution information. For example, a sensor for measurement is provided in a ceiling of the measurement chamber, and the sensor measures an irregularity distribution of the surface of the focus ring 31 transferred into the measurement chamber by the transfer arm 190. The measurement chamber may be a location dedicated to measurement in which substrate processing such as etching is not performed, or may be a location used jointly for the substrate processing.

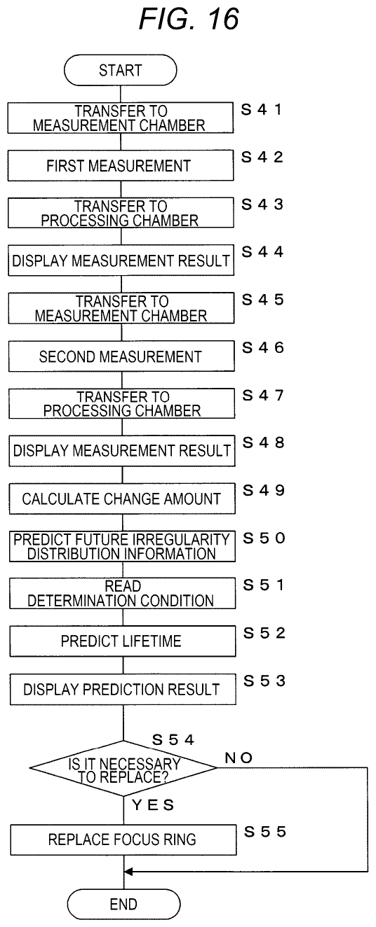

FIG. 16 is a flowchart illustrating an example of a procedure of lifetime prediction processing performed by the substrate processing system 100 according to a third embodiment. The transfer arm control processor 41f of the processor 41 of the substrate processing system 100 according to the third embodiment controls the operation of the transfer arm 190 to transfer the focus ring 31 to be measured to the measurement chamber in which the sensor is provided (step S41). The irregularity distribution information acquirer 41a of the processor 41 performs the first measurement of the irregularity distribution information by measuring the irregularity distribution by the sensor in the measurement chamber and acquiring a measurement result (step S42). The transfer arm control processor 41f controls the operation of the transfer arm 190 to transfer the focus ring 31 after the measurement into the processing chamber 102 (step S43). The display processor 41e of the processor 41 displays the first measurement result obtained in step S42 on the display 44 (step S44).

After the first measurement is completed, the substrate processing system 100 performs substrate processing such as etching over a predetermined time. Thereafter, as in the first measurement, the transfer arm control processor 41f controls the operation of the transfer arm 190 to transfer the focus ring 31 to be measured to the measurement chamber in which the sensor is provided (step S45). The irregularity distribution information acquirer 41a performs the second measurement of the irregularity distribution information by measuring the irregularity distribution by the sensor in the measurement chamber and acquiring a measurement result (step S46). The transfer arm control processor 41f controls the operation of the transfer arm 190 to transfer the focus ring 31 after the measurement into the processing chamber 102 (step S47). The display processor 41e displays the second measurement result obtained in step S46 on the display 44 (step S46).

Thereafter, the change probability calculator 41b calculates a change probability relating to the distribution of the irregularities on the surface of the focus ring 31 (step S49). The irregularity distribution predictor 41c predicts future irregularity distribution information (step S50). The lifetime predictor 41d reads a determination condition for predicting the lifetime of the focus ring 31 from the determination condition storage 42c of the storage 42 (step S51). The lifetime predictor 41d predicts the lifetime of the focus ring 31 based on the read determination condition (step S52). The display processor 41e displays the prediction result of the lifetime on the display 44 (step S53).

The lifetime predictor 41d determines whether it is necessary to replace the focus ring 31 based on the prediction result of the lifetime (step S54). When it is necessary to replace the focus ring 31 (S54: YES), the transfer arm control processor 41f of the processor 41 performs control processing of replacing the focus ring 31 (step S55), and ends the processing. When it is not necessary to replace the focus ring 31 (S54: NO), the processor 41 ends the processing.

Since the other configurations of the information processing system according to the third embodiment are the same as those of the information processing systems according to the first embodiment and the second embodiment, the same reference numerals are given to the same locations, and a detailed description thereof will be omitted.

According to the present disclosure, it can be expected to predict a state of the chamber internal component of the substrate processing apparatus.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. An information processing method comprising:
acquiring distribution information of irregularities on a surface of a chamber internal component of a substrate processing apparatus at a first time point;
acquiring distribution information of irregularities of the chamber internal component at a second time point after substrate processing is performed from the first time point; and
predicting distribution information of irregularities of the chamber internal component at a time point after the substrate processing is performed from the second time point, based on the acquired distribution information at the first time point and distribution information at the second time point.

2. The information processing method according to claim 1, further comprising:
predicting a lifetime of the chamber internal component based on the predicted distribution information.

3. The information processing method according to claim 1, wherein
based on the distribution information at the first time point and the distribution information at the second time point, a distribution of a probability of a change in a height of the irregularities of the chamber internal component caused by the substrate processing is calculated as a change probability, and
predicting the distribution information of the irregularities of the chamber internal component at a time point after the second time point based on the calculated change probability.

4. The information processing method according to claim 3, further comprising:
calculating a difference between a height of an irregularity extracted from the distribution information at the first time point and a height of an irregularity extracted from the distribution information at the second time point;
calculating the difference a plurality of times to calculate the change probability of the irregularities; and
changing the distribution information at the second time point according to the calculated change probability, so that distribution information of the irregularities of the chamber internal component at a time point after the second time point is predicted.

5. The information processing method according to claim 1, wherein
the chamber internal component includes a holder that holds a specimen for acquiring the distribution information, and
acquiring distribution information of irregularities on a surface of the specimen as the distribution information of the irregularities of the chamber internal component.

6. The information processing method according to claim 1, further comprising:
acquiring, via a sensor provided in a transfer arm that transfers a substrate, the distribution information of the irregularities on the surface of the chamber internal component.

7. The information processing method according to claim 1, further comprising:
transferring the chamber internal component to a predetermined measurement location by a transfer arm that transfers a substrate, and acquiring, via a sensor provided at the measurement location, the distribution information of the irregularities on the surface of the chamber internal component.

8. The information processing method according to claim 1, further comprising:
replacing the chamber internal component according to a prediction result of the distribution information.

9. A non-transitory computer-readable medium storing executable instruction which, when executed by controller circuitry, cause the controller circuitry to execute a method, the method comprising:
acquiring distribution information of irregularities on a surface of a chamber internal component of a substrate processing apparatus at a first time point;
acquiring distribution information of irregularities of the chamber internal component at a second time point after substrate processing is performed from the first time point; and
predicting distribution information of irregularities of the chamber internal component at a time point after the substrate processing is performed from the second time point, based on the acquired distribution information at the first time point and distribution information at the second time point.

10. An information processing apparatus comprising:
controller circuitry, wherein
the controller circuitry is configured to
acquire distribution information of irregularities on a surface of a chamber internal component of a substrate processing apparatus at a first time point,
acquire distribution information of irregularities of the chamber internal component at a second time point after substrate processing is performed from the first time point, and
predict distribution information of irregularities of the chamber internal component at a time point after the substrate processing is performed from the second time point, based on the acquired distribution information at the first time point and distribution information at the second time point.

11. A substrate processing system comprising:
a sensor configured to acquire distribution information of irregularities on a surface of a chamber internal component provided in a chamber accommodating a substrate subjected to substrate processing, and
controller circuitry configured to predict the distribution information of the irregularities of the chamber internal component, wherein the controller circuitry is configured to
acquire distribution information of irregularities on the surface of the chamber internal component at a first time point,
acquire distribution information of irregularities of the chamber internal component at a second time point after the substrate processing is performed from the first time point, and
predict distribution information of irregularities of the chamber internal component at a time point after the substrate processing is performed from the second time point, based on the acquired distribution information at the first time point and distribution information at the second time point.

12. The substrate processing system according to claim 11, further comprising:
a transfer arm to transfer the substrate and the chamber internal component provided in the chamber, wherein
the sensor is provided in the transfer arm.

13. The substrate processing system according to claim 11, further comprising:
a measurement location where a measurement is performed by the sensor, and
a transfer arm to transfer the chamber internal component between the chamber and the measurement location, wherein
the chamber internal component is transferred by the transfer arm from inside the chamber to the measurement location, and distribution information is acquired by the sensor.

14. The substrate processing system according to claim 12, wherein
the chamber internal component is replaced by the transfer arm according to a prediction result of the distribution information.

15. The substrate processing system according to claim 13, wherein
the chamber internal component is replaced by the transfer arm according to a prediction result of the distribution information.

16. The information processing method according to claim 3, further comprising:
calculating a difference between a height of an irregularity extracted from the distribution information at the first time point and a height of an irregularity extracted from the distribution information at the second time point.

17. The information processing method according to claim 1, wherein
the chamber internal component includes a holder that holds a specimen for acquiring the distribution information.

18. The non-transitory computer-readable medium of claim 9, the method further comprising:
predicting a lifetime of the chamber internal component based on the predicted distribution information.

19. The non-transitory computer-readable medium of claim 9, wherein
based on the distribution information at the first time point and the distribution information at the second time point, a distribution of a probability of a change in a height of the irregularities of the chamber internal component caused by the substrate processing is calculated as a change probability, and
predicting the distribution information of the irregularities of the chamber internal component at a time point after the second time point based on the calculated change probability.

20. The information processing method according to claim 19, the method further comprising:
calculating a difference between a height of an irregularity extracted from the distribution information at the first time point and a height of an irregularity extracted from the distribution information at the second time point;
calculating the difference a plurality of times to calculate the change probability of the irregularities; and
changing the distribution information at the second time point according to the calculated change probability, so that distribution information of the irregularities of the chamber internal component at a time point after the second time point is predicted.
